(19) United States
(12) Patent Application Publication
(10) Pub. No.: US 2013/0178006 A1
(43) Pub. Date: Jul. 11, 2013

(54) WAFER DICING METHOD AND METHOD OF MANUFACTURING LIGHT EMITTING DEVICE CHIPS EMPLOYING THE SAME

(71) Applicant: SAMSUNG ELECTRONICS CO., LTD., Suwon-si (KR)

(72) Inventors: Nam-seung KIM, Suwon-si (KR); Yu-sik KIM, Seoul (KR)

(73) Assignee: SAMSUNG ELECTRONICS CO., LTD., Suwon-si (KR)

(21) Appl. No.: 13/719,489

(22) Filed: Dec. 19, 2012

(30) Foreign Application Priority Data
Jan. 10, 2012 (KR) 10-2012-0003076

(51) Int. Cl. H01L 21/78; H01L 33/00

(52) U.S. Cl. CPC H01L 21/78; H01L 33/005
USPC 438/33; 438/460; 438/462

(57) ABSTRACT

A wafer dicing method includes forming a semiconductor device on a first surface of a wafer; first-dicing a portion of the wafer and the semiconductor device; and splitting the wafer and the semiconductor device into a plurality of semiconductor device chips by second-dicing the wafer that has been first-diced.

### CROSS-REFERENCE TO RELATED APPLICATION

This application claims the priority from Korean Patent Application No. 10-2012-0003076, filed on Jan. 10, 2012 in the Korean Intellectual Property Office, the disclosure of which is incorporated herein by reference in its entirety.

### BACKGROUND

1. Field

Apparatuses and methods consistent with inventive concept relate to wafer dicing and manufacturing light emitting device (LED) chips, and more particularly, to wafer dicing for forming a plurality of chips by first-dicing a portion of a wafer, performing additional operations thereon, and then second-dicing the wafer, and a method of manufacturing LED chips employing the wafer dicing method.

2. Description of the Related Art

In a semiconductor package assembly process, a dicing process is a process for dicing a plurality of semiconductor chips included in a wafer or a process for separating a wafer into individual semiconductor chips, such that the individual semiconductor chips may be mounted on basic frames for semiconductor packages, e.g., lead frames or printed circuit boards.

The dicing process may be performed by using a blade, a laser, plasma etching, etc. Recently, due to the improvements in the capacity, speed, and miniaturization of semiconductor devices, low-k materials have become popular for insulation between metals. The low-k materials include materials having permittivity smaller than the dielectric constant of a silicon oxide.

However, when a wafer containing a low-k material is diced by using a blade, the semiconductor chips are often partially chipped or semiconductor chips often crack. To eliminate such defects, new dicing methods capable of preventing the occurrence of chipping defects or crack defects during a semiconductor package assembly process have been developed.

For example, in a blade dicing method, a method in which a wafer is diced by adjusting a rotational speed of a blade has been proposed, to reduce the chipping and crack defects. However, when a wafer is diced by adjusting a rotational speed of a blade, the occurrence of chipping defects or crack defects may be reduced, but it is difficult to obtain high quality semiconductor chips. Furthermore, when the rotational speed of a blade is adjusted, a number of semiconductor chips diced per unit period of time is decreased, and thus, productivity is deteriorated.

Accordingly, dicing processes using laser or plasma etching have gradually replaced the blade dicing methods. However, in a laser dicing method, it is necessary to separately coat active surfaces of semiconductor chips with an expensive coating material to prevent diced silicon particles from being welded to the active surfaces of the semiconductor chips while a groove is being formed along scribe lines of a wafer or the wafer is completely diced along the scribe lines. Additionally, a laser for forming grooves is different from a laser for completely dicing a wafer along scribe lines, and a die attach film (DAF) is not diced smoothly while a wafer is being completely diced along scribe lines.

Furthermore, in a dicing process using plasma etching, an etch mask is necessary to prevent surfaces of semiconductor chips from being etched while a wafer is being diced along scribe lines. However, in a wafer manufacturing process, an etch mask is typically formed in a separate photolithography process, which makes the overall semiconductor packaging process complex and raises the overall manufacturing cost.

### SUMMARY

Exemplary embodiments may address at least the above problems and/or disadvantages and other disadvantages not described above. Also, exemplary embodiments are not required to overcome the disadvantages described above, and an exemplary embodiment may not overcome any of the problems described above.

One or more exemplary embodiments provide wafer dicing methods and methods of manufacturing LED chips employing the same.

According to an aspect of an exemplary embodiment, a wafer dicing method includes forming a semiconductor device on a first surface of a wafer; first-dicing a portion of the wafer and the semiconductor device; and splitting the wafer and the semiconductor device into a plurality of semiconductor device chips by second-dicing a portion of the wafer that is first-diced.

In the first-dicing, grooves having a depth corresponding to from 30% to 70% of thickness of the wafer are formed in the wafer.

In the first-dicing, grooves having a depth corresponding to from 40% to 60% of thickness of the wafer are formed in the wafer.

The grooves include a plurality of first grooves formed on the wafer in parallel to a first direction; and a plurality of second grooves formed on the wafer in parallel to a second direction that is perpendicular to the first direction.

The first-dicing is performed by using a blade, a laser, or plasma etching.

In the second-dicing, the portion that is first-diced is broken by applying a physical force to a second surface of the wafer, wherein the second surface is the surface opposite to the first surface.

The physical force is applied to the wafer via a cutter having an unsharpened edge.

The wafer dicing method further includes attaching a dicing tape onto the second surface of the wafer.

The wafer dicing method further includes performing additional processes to the semiconductor devices.

The additional processes include forming an additional layer on the semiconductor devices.

According to another aspect of an exemplary embodiment, there is provided a method of manufacturing LED chips, the method including forming LEDs on a first surface of a wafer; first-dicing a portion of the wafer and the LEDs; and splitting the wafer and the LEDs to a plurality of LED chips by second-dicing a portion of the wafer that is first-diced.

The LED includes a stacked structure in which an n-type semiconductor layer, an active layer, and a p-type semiconductor layer are stacked in the order stated.

In the first-dicing, grooves having a depth corresponding to from 30% to 70% of thickness of the wafer are formed in the wafer.

In the first-dicing, grooves having a depth corresponding to from 40% to 60% of thickness of the wafer are formed in the wafer.

The grooves include a plurality of first grooves formed in the wafer in parallel to a first direction; and a plurality of second grooves formed in the wafer in parallel to a second direction that is perpendicular to the first direction.

The first-dicing is performed by using a blade, a laser, or plasma etching.

In the second-dicing, the portion that is first-diced is broken by applying a physical force to a second surface of the wafer, wherein the second surface is the surface opposite to the first surface.

The physical force is applied to the wafer via a cutter having an unsharpened edge.

The method further includes performing additional processes to the semiconductor devices.

The additional layer includes a phosphor material.

The additional layer is formed via screen printing.

The method further includes attaching a dicing tape onto the second surface of the wafer.

### BRIEF DESCRIPTION OF THE DRAWINGS

The above and/or other aspects will become more apparent by describing certain exemplary embodiments, with reference to the accompanying drawings, in which:

FIGS. 1A through 1F are schematic diagrams showing a wafer dicing method according to an exemplary embodiment;

FIGS. 2A through 2F are schematic diagrams showing a method of manufacturing LED chips according to an exemplary embodiment;

FIGS. 3A and 3B are top-view pictures of LED chips manufactured according to an exemplary embodiment; and

FIGS. 4A and 4B are top-view pictures of LED chips manufactured according to a comparative embodiment.

### DETAILED DESCRIPTION

Certain exemplary embodiments are described in greater detail below, with reference to the accompanying drawings.

In the following description, like drawing reference numerals are used for the like elements, even in different drawings. The matters defined in the description, such as detailed construction and elements, are provided to assist in a comprehensive understanding of exemplary embodiments. However, exemplary embodiments can be practiced without those specifically defined matters. Also, well-known functions or constructions are not described in detail since they would obscure the application with unnecessary detail.

A wafer dicing method according to an exemplary embodiment is described below in detail.

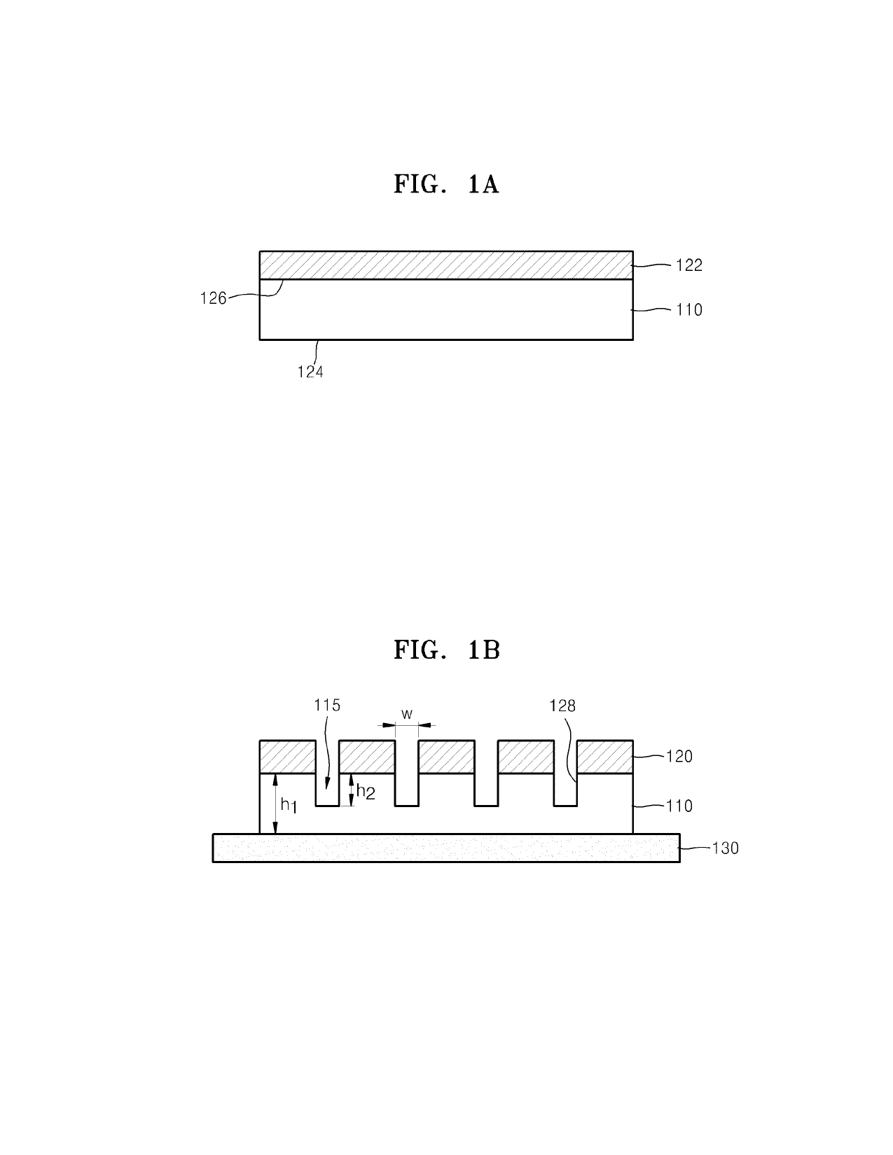

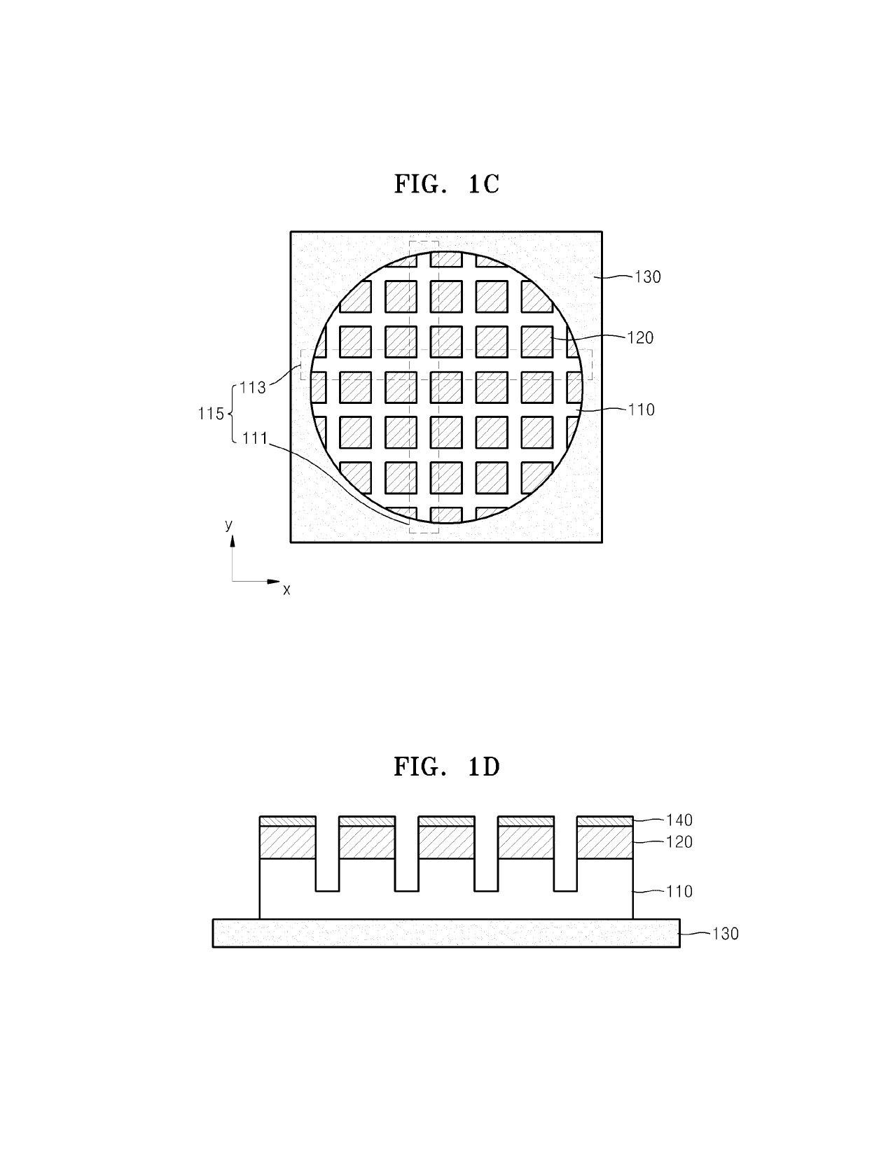

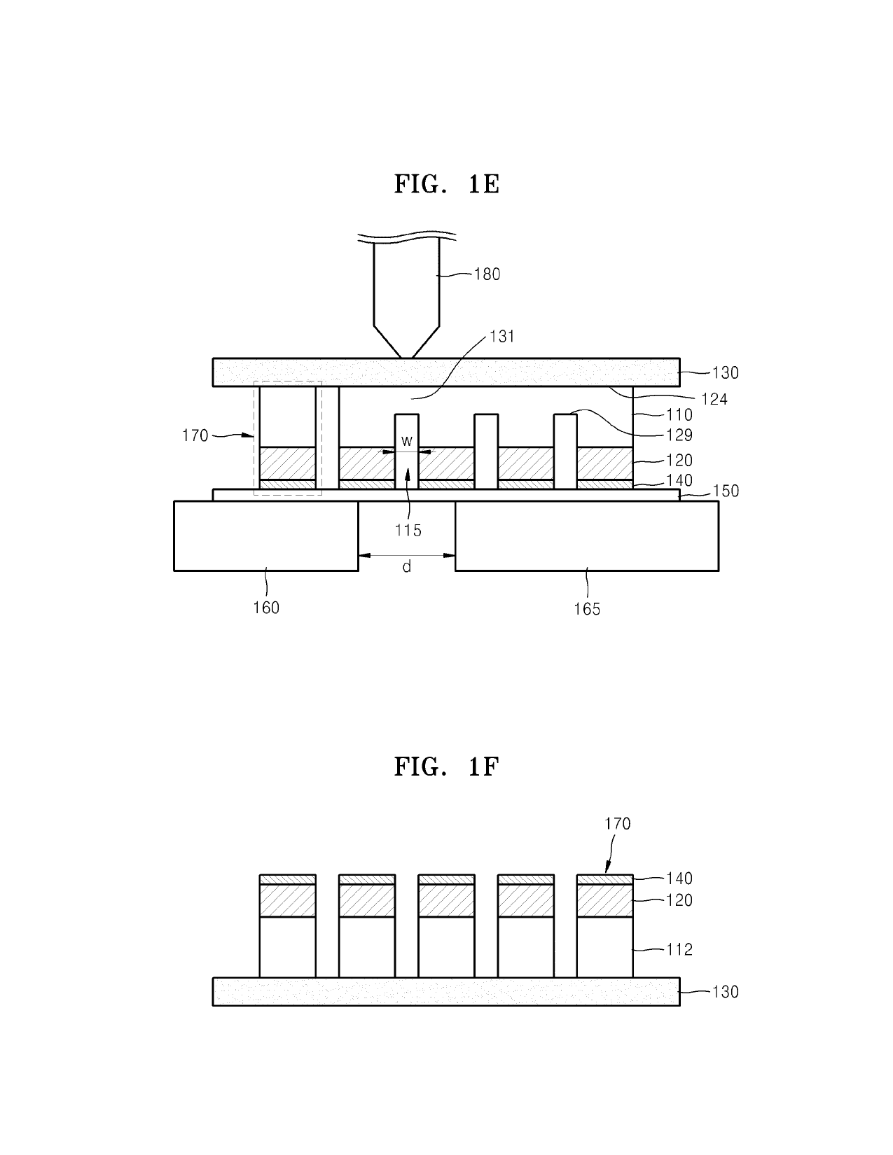

FIGS. 1A through 1F are schematic diagrams showing a wafer dicing method according to an exemplary embodiment.

Referring to FIG. 1A, a wafer 110 is provided, and a semiconductor device 122 may be formed on the wafer 110. The wafer 110 may be formed of Si, SiAl, GaAs, Ge, SiGe, AlN, GaN, AlGaN, SiC, ZnO, or AlSiC. However, an exemplary embodiment is not limited thereto. The semiconductor device 122 may include at least one from among a semiconductor layer, an insulation layer, and a metal layer.

Referring to FIG. 1B, a dicing tape 130 may be attached to the first or rear surface 124 of the wafer 110, that is, the surface of the wafer 110 opposite to the second surface 126 of the wafer 110 on which the semiconductor device 122 is formed. The dicing tape 130 is a film having adhesiveness for fixing or supporting the wafer 110 while the wafer 110 is being diced. The dicing tape 130 may include a base film formed of a polymer resin and an adhesive layer arranged on a surface of the base film. The base film may be formed of polyvinyl chloride (PVC), polyolefin (PO), or polyethylene terephthalate (PET), for example. The adhesive layer may be formed of an acrylic resin.

Next, a portion of the wafer 110 and the semiconductor device 122 may be first-diced. In the first-dicing operation, the single semiconductor device 122 may be split into a plurality of semiconductor devices 120. Furthermore, in the first-dicing operation, a plurality of grooves 115 may be formed in the wafer 110, by cutting out first-diced portions from a first portion 128 of the wafer 110. However, in the first-dicing operation, the wafer 110 is not completely diced into a plurality of wafers 112. Since only portions of the wafer 110 are removed in a thickness direction, in the first-dicing operation, the first-dicing operation may be referred to as a half-dicing or a partial-dicing operation. The first-dicing operation may be performed by using a blade, a laser, or plasma etching. In other words, the plurality of grooves 115 may be formed by using a blade, a laser, or plasma etching.

Depth h2 of the grooves 115 may be from about 30% to about 70% of thickness h1 of the wafer 110. More particularly, the depth h2 of the grooves 115 may be from about 40% to about 60% of the thickness h1 of the wafer 110. Furthermore, more particularly, the depth h2 of the grooves 115 may be about 50% of the thickness h1 of the wafer 110. For example, if the thickness h1 of the wafer 110 is from about 10 μm to about 1000 μm, the depth h2 of the grooves 115 may be from about 5 μm to about 500 μm. For example, if the thickness h1 of the wafer 110 is about 140 μm, the depth h2 of the grooves 115 may be about 70 μm.

The width w of the grooves 115 may be in tens of μm and may be from about 10 μm to about 90 μm, for example. The smaller the width w of the grooves 115 (that is, an interval between the plurality of semiconductor devices 120) is, the more semiconductor devices 120 may be formed on the wafer 110 having a limited size.

FIG. 1C is a top view of the wafer 110 and the semiconductor devices 120 shown in FIG. 1B. Referring to FIG. 1C, the wafer 110 is attached onto the dicing tape 130, and the plurality of semiconductor devices 120 arranged on the wafer 110 may be separated by the grooves 115. However, since the grooves 115 are not formed to penetrate through the wafer 110, the wafer 110 and the semiconductor devices 120 are not completely split into a plurality of semiconductor device chips at this point. For example, the grooves 115 may include a plurality of first grooves 111 formed in the wafer 110 in a first direction parallel to the y-axis direction and a plurality of second grooves 113 formed in the wafer 110 in a second direction parallel to the x-axis direction. The plurality of semiconductor devices 120 may be arranged in a two-dimensional array separated by the first and second grooves 111 and 113.

Referring to FIG. 1D, an additional process may be performed on the semiconductor devices 120. The additional process may include a step of forming an additional layer 140 on the semiconductor devices 120. The additional layer 140 may include a phosphor layer, an insulation layer, a protective layer, or a metal layer. When the additional layer 140 is formed on the semiconductor device 122 and the wafer 110 is subsequently completely diced, a material constituting the semiconductor device 122 and a material constituting the wafer 110 may contaminate the additional layer 140. However, as described above, if the additional layer 140 is formed on the semiconductor devices 120 after the wafer 110 and the semiconductor device 122 are first-diced, such process may prevent the additional layer 140 from being contaminated by a material constituting the semiconductor devices 120 and a material constituting the wafer 110.

Furthermore, when the wafer 110 and the semiconductor device 122 are completely diced and the additional layer 140 is formed on the plurality of semiconductor devices 120 by using a coating mask, an arrangement of the completely diced wafers and semiconductor devices may be modified due to expansion of the dicing tape 130. Therefore, alignment between the coating mask and the plurality of semiconductor devices 120 may be modified, and thus, the additional layer 140 may formed improperly on the plurality of semiconductor devices 120. However, as described above, in a case where the additional layer 140 is formed on the semiconductor devices 120 after the wafer 110 and the semiconductor device 122 are first-diced, the wafer 110 and the semiconductor devices 120 are not completely separated, and thus, even if the dicing tape 130 is expanded, the two-dimensional arrangement of the semiconductor devices 120 may be maintained. Therefore, the additional layer 140 may be properly formed only on the plurality of semiconductor devices 120.

Referring to FIG. 1E, the wafer 110 may be second-diced through a second portion 131 disposed proximate the bottom surfaces 129 of the grooves 115. In the second-dicing process, the wafer 110 may be completely broken by applying a physical force to the areas of the second portion 131 proximate the bottom surfaces of the grooves 115 of the wafer 110. The physical force may be applied when a cutter 180 having an unsharpened edge is used. Therefore, the wafer 110 and the semiconductor devices 120 may be split into a plurality of semiconductor device chips 170.

First, a protective film 150 may be attached on the top surface of the additional layer 140. Next, the wafer 110 may be turned upside down, such that the protective film 150 faces downward, and the wafer 110 may be arranged on first and second supporting units 160 and 165. The protective film 150 may prevent the additional layer 140 from being damaged by directly contacting the first and second supporting units 160 and 165. The protective film 150 may be formed of a polymer resin, e.g., PET, PVC, PO, etc. The first and second supporting units 160 and 165 are arranged apart from each other, and a distance d therebetween may be greater than the width of the grooves 115 formed on the wafer 110. The wafer 110 may be moved to locate the grooves 115 between the first and second supporting units 160 and 165 and physical force may be applied to the rear surface 124 of the wafer 110, which is the surface on which the dicing tape 130 is attached, by using the cutter 180. Therefore, areas of the second portion 131 of the wafer 110 proximate the bottom surfaces 129 of the grooves 115 and corresponding to the grooves 115, are diced, and thus, the wafer 110 and the semiconductor devices 120 may be split into the plurality of semiconductor device chips 170, by cutting into the grooves 115.

Referring to FIG. 1F, the plurality of semiconductor device chips 170 that are separated in the second-dicing process may be arranged on the dicing tape 130. After the second-dicing process is completed, the dicing tape 130 attached to the bottom surfaces of the plurality of semiconductor device chips 170 may be removed. The dicing tape 130 may be a pressure sensitive adhesive tape or a UV curable tape. However, an exemplary embodiment is not limited thereto. For example, if the dicing tape 130 is a UV curable tape, irradiating a UV light to the bottom surface of the wafer 110 may make an adhesive layer of the dicing tape 130 cured, such that the dicing tape 130 may be peeled off from the semiconductor device chips 170.

Next, a method of manufacturing LED chips according to an exemplary embodiment will be described in detail.

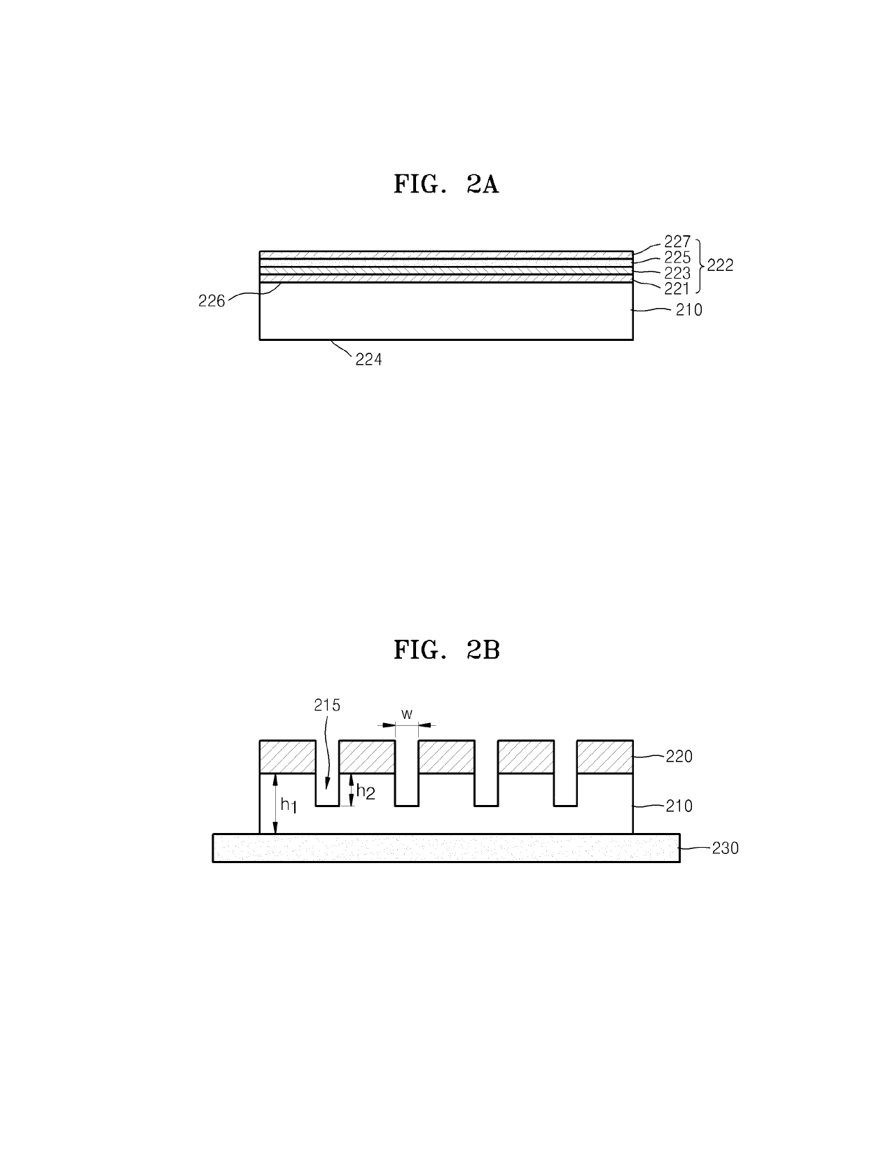

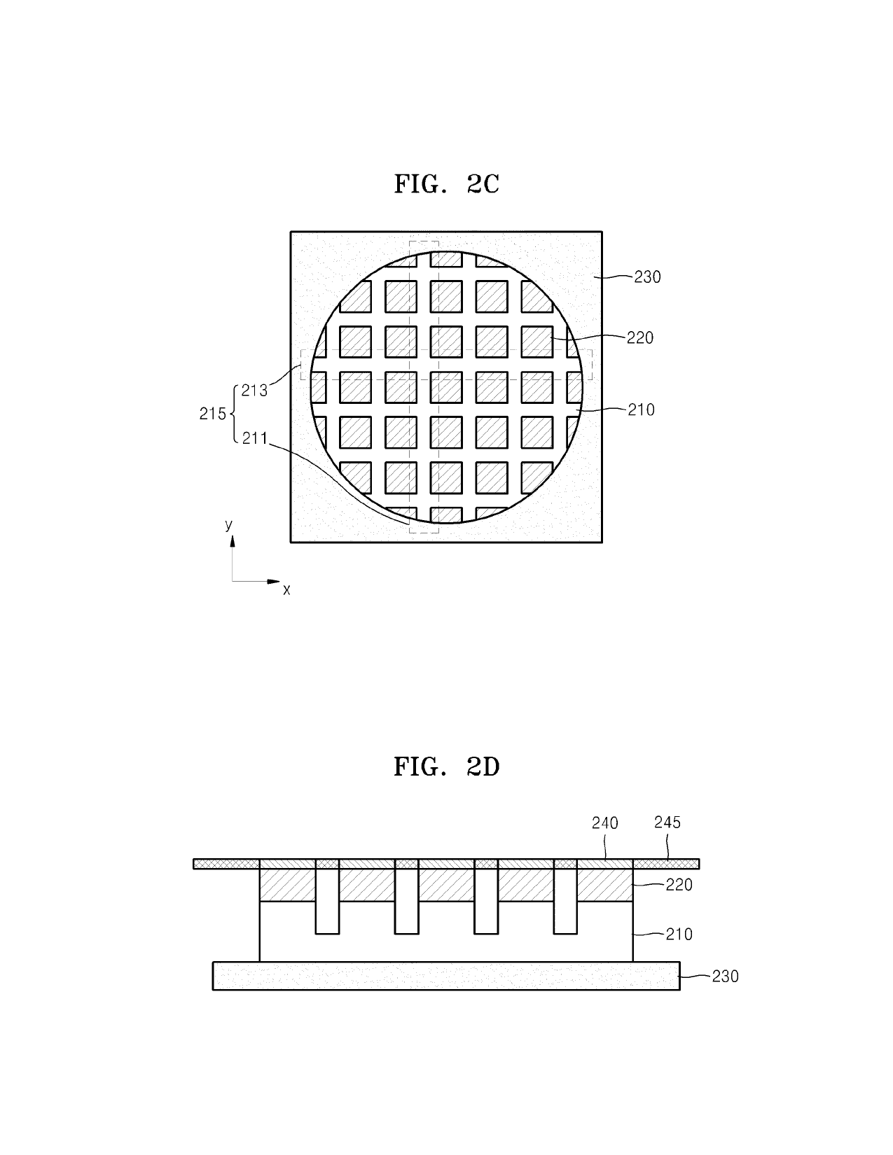

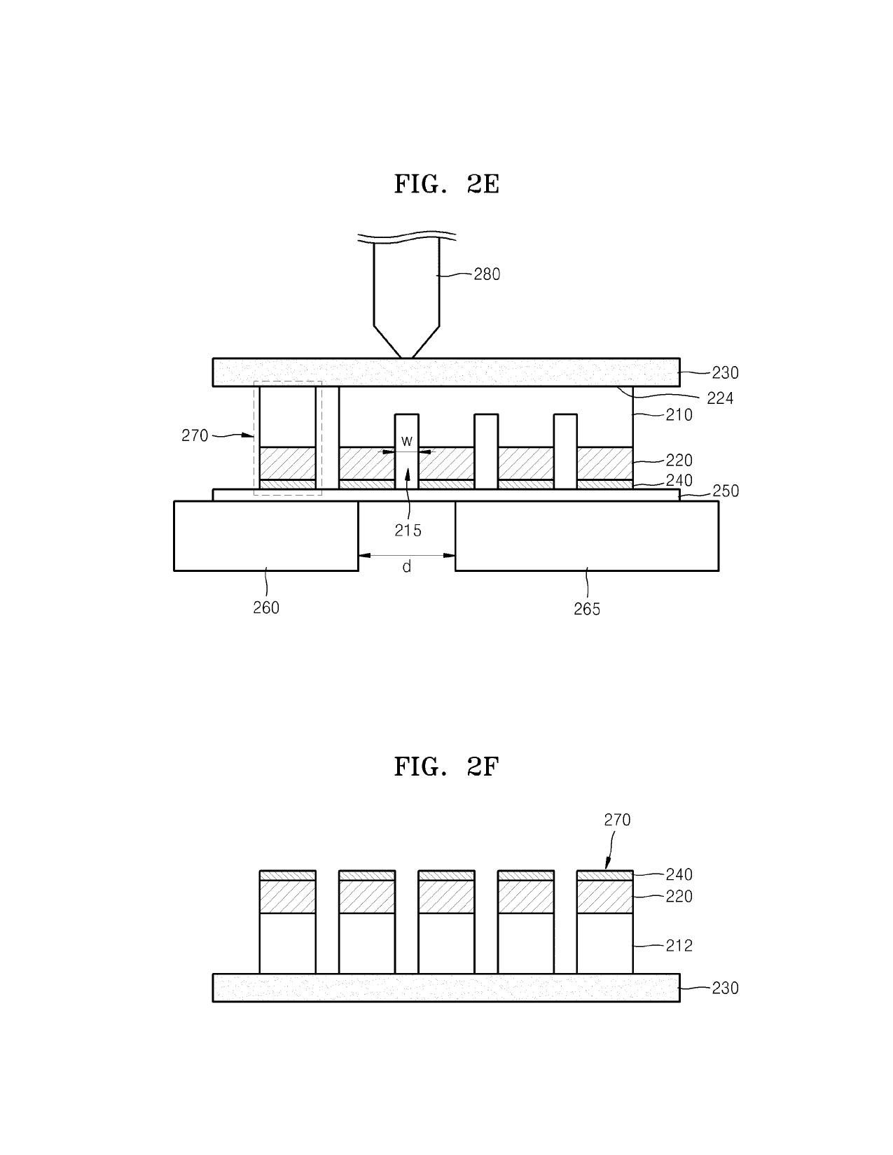

FIGS. 2A through 2F are schematic diagrams showing a method of manufacturing LED chips according to an exemplary embodiment.

Referring to FIG. 2A, a wafer 210 is provided, and an LED 222 may be formed on the wafer 210. The wafer 210 may be formed of Si, SiAl, GaAs, Ge, SiGe, AlN, GaN, AlGaN, SiC, ZnO, or AlSiC. However, an exemplary embodiment is not limited thereto. The LED 222 may have a stacked structure, in which a buffer layer 221, an n-type semiconductor layer 223, an active layer 225, and a p-type semiconductor layer 227 are stacked on the wafer 210 in this order.

The buffer layer 221 may be formed of a material capable of reducing stress due to a difference between lattice constants of the wafer 210 and the n-type semiconductor layer 223. The buffer layer 221 may be formed of GaN, AlN, AlGaN, etc.

The n-type semiconductor layer 223 may be formed of a nitride semiconductor doped with an n-type impurity. The n-type semiconductor layer 223 may be formed by doping a semiconductor material having a composition of AlₓIn_{y}Ga_{(1-x-y)}N (here, 0≦x≦1, 0≦y≦1, and 0≦x+y≦1) with an n-type impurity. For example, the n-type semiconductor layer 223 may contain GaN, AlGaN, InGaN, etc., whereas the n-type impurity may include N, P, As, Sb, Si, Ge, Se, Te, etc.

The active layer 225 emits light having a predetermined energy as electrons and holes are recombined and may be formed of a semiconductor material, such as InₓGa₁₋ₓN (0≦x≦1), such that band gap energy may be controlled according to the indium content. The active layer 225 may be a multi-quantum well (MQW) layer in which quantum barrier layers and quantum well layers are alternately stacked.

The p-type semiconductor layer 227 may be formed of a nitride semiconductor doped with a p-type impurity. The p-type semiconductor layer 227 may be formed by doping a semiconductor material having a composition of AlₓIn_{y}Ga_{(1-x-y)}N (here, 0≦x≦1, 0≦y≦1, and 0≦x+y≦1) doped with a p-type impurity. For example, the p-type semiconductor layer 227 may contain GaN, AlGaN, InGaN, etc., whereas the p-type impurity may include B, Zn, Mg, Be, etc. The LED 222 may further include an insulation layer, an electrode layer, a reflective layer, etc., and a sequence of stacking the n-type and p-type semiconductor layers 223 and 227 may vary. For convenience of explanation, descriptions of layers included in the LED 222 are omitted below.

Referring to FIG. 2B, a dicing tape 230 may be attached to the first or rear surface 224 of the wafer 210, that is, the surface opposite to the second or top surface 226 of the wafer 210 on which the LED 222 is formed. The dicing tape 230 is an adhesive film for fixing or supporting the wafer 210 while the wafer 210 is being diced. The dicing tape 230 may include a base film formed of a polymer resin and an adhesive layer arranged on a surface of the base film. The base film may be formed of polyvinyl chloride (PVC), polyolefin (PO), or polyethylene terephthalate (PET), etc. The adhesive layer may be formed of an acrylic resin, etc.

Next, a portion of the wafer 210 and the LED 222 may be first-diced. In the first-dicing process, the LED 222 may be split into a plurality of LEDs 220. Furthermore, in the first-dicing process, a plurality of grooves 215 may be formed in the wafer 210. However, in the first-dicing process, the wafer 210 is not completely diced into the plurality of wafers 212. Since only a partial portion of the wafer 210 is removed in the first-dicing process, the first-dicing process may be referred to as a half-dicing or a partial-dicing process. The first-dicing process may be formed by using a blade, a laser, or plasma etching. In other words, the plurality of grooves 215 may be formed by using a blade, a laser, or plasma etching.

Depth h2 of the grooves 215 may be from about 30% to about 70% of a thickness h1 of the wafer 210. More particularly, the depth h2 of the grooves 215 may be from about 40% to about 60% of the thickness h1 of the wafer 210. More particularly, the depth h2 of the grooves 215 may be about 50% of the thickness h1 of the wafer 210. For example, if the thickness h1 of the wafer 210 is from about 10 μm to about 1000 μm, the depth h2 of the grooves 215 may be from about 5 μm to about 500 μm. For example, if the thickness h1 of the wafer 210 is about 140 μm, the depth h2 of the grooves 215 may be about 70 μm.

The width w of the grooves 215 may be dozens of μm, e.g., from about 10 μm to about 90 μm. As the width w of the grooves 215, that is, the distance between the plurality of LEDs 220, becomes smaller, the more LEDs 220 may be formed on the wafer 210 having a limited area.

FIG. 2C is a plan view showing the wafer 210 and the LEDs 220 of FIG. 2B. Referring to FIG. 2C, the wafer 210 is attached onto the dicing tape 230, and the plurality of LEDs 220 arranged on the wafer 210 may be split by the grooves 215. However, since the grooves 215 are not formed to completely penetrate the wafer 210, the wafer 210 and the LEDs 220 are not yet split into a plurality of LED chips. The grooves 215 may include a plurality of first grooves 211 formed in parallel to a first direction, e.g., the y-axis direction, and a plurality of second grooves 213 formed in parallel to a second direction that is perpendicular to the first direction, e.g., the x-axis direction. The plurality of LEDs 220 may be arranged in a two-dimensional array separated by the first and second grooves 211 and 213.

Referring to FIG. 2D, additional processes may be performed to the LEDs 220. The additional processes may include a process for forming a phosphor layer 240 on the LEDs 220, for example. The phosphor layer 240 may be formed via deposition, sputtering, spray coating, deep coating, spin coating, screen printing, inkjet printing, gravure printing, or by using a doctor blade. For example, the phosphor layer 240 may include phosphors printed on the LEDs 220 by using a screen printing mask 245. Furthermore, the additional processes may include a process for forming an insulation layer or a protective layer.

If the phosphor layer 240 is formed on the LED 222 and the wafer 210 and the LED 222 are subsequently diced, materials constituting the LED 222 and the wafer 210 may contaminate the phosphor layer 240. However, according to the method of manufacturing LED chips according to the present exemplary embodiment, if the phosphor layer 240 is formed on the LEDs 220 after the wafer 210 and the LED 222 are first-diced, the phosphor layer 240 may be prevented from being contaminated by materials constituting the LEDs 220 and the wafer 210 during a dicing process.

Furthermore, if the wafer 210 and the LED 222 are completely diced and the phosphor layer 240 is formed on the plurality of LEDs 220 by using the screen printing mask 245, the two-dimensional arrangement of the plurality of wafers 212 and the plurality of LEDs 220 that are completely diced may be dislocated due to the expansion of the dicing tape 230. Therefore, the alignment between the screen printing mask 245 and the plurality of LEDs 220 is dislocated, and thus, the phosphor layer 240 may be improperly printed on the plurality of LEDs 220. However, according to the method of manufacturing LED chips according to the present exemplary embodiment, if the phosphor layer 240 is formed on the LEDs 220 after the wafer 210 and the LED 222 are first-diced, the wafer 210 and the LEDs 220 are not completely separated. Therefore, even if the dicing tape 230 expands, the two-dimensional arrangement of the wafer 210 and the LEDs 220 may be maintained. Therefore, the phosphor layer 240 may be properly printed only on the plurality of LEDs 220.

Next, referring to FIG. 2E, the portion of the wafer 210 adjacent to the grooves 215 may be second-diced. In the second-dicing process, the wafer 210 may be completely broken by applying a physical force to the portions of wafer 210 proximate the lower surfaces of the grooves 215 of the wafer 210. The physical force may be applied by using a cutter 280 having an unsharpened edge. Therefore, the wafer 210 and the LEDs 220 may be split into a plurality of semiconductor device chips 270.

First, a protective film 250 may be attached onto the top surface of the phosphor layer 240. Next, the wafer 210 may be turned upside down, such that the protective film 250 faces downward. As a result, the wafer 210 may be arranged on first and second supporting units 260 and 265. The protective film 250 may prevent the phosphor layer 240 from being damaged by directly contacting the first and second supporting units 260 and 265. The protective film 250 may be formed of a polymer resin, e.g., PET, PVC, PO, etc. The first and second supporting units 260 and 265 are arranged apart from each other, and a distance d therebetween may be greater than the width w of the grooves 215 formed on the wafer 210. The wafer 210 may be moved to locate the grooves 215 between the first and second supporting units 260 and 265 and a physical force may be applied to the rear surface 224 of the wafer 210, which is the surface on which the dicing tape 230 is attached, by using the cutter 280. Therefore, the portions of the wafer 210 which were not first-diced, that is, the portions proximate the bottom surfaces of the grooves 215 are diced, and thus the wafer 210 and the LEDs 220 may be split into the plurality of semiconductor device chips 270.

Referring to FIG. 2F, the plurality of semiconductor device chips 270 that are separated in the second-dicing process may be arranged on the dicing tape 230. After the second-dicing process is completed, the dicing tape 230 attached to the bottom surfaces of the plurality of semiconductor device chips 270 may be removed. The dicing tape 230 may be a pressure sensitive adhesive tape or a UV curable tape. However, an exemplary embodiment is not limited thereto. For example, if the dicing tape 230 is a UV curable tape, irradiating a UV light to the bottom surface of the wafer 210 may make an adhesive layer of the dicing tape 230 be cured, such that the dicing tape 230 may be peeled off from the semiconductor device chips 270 by reducing adhesiveness.

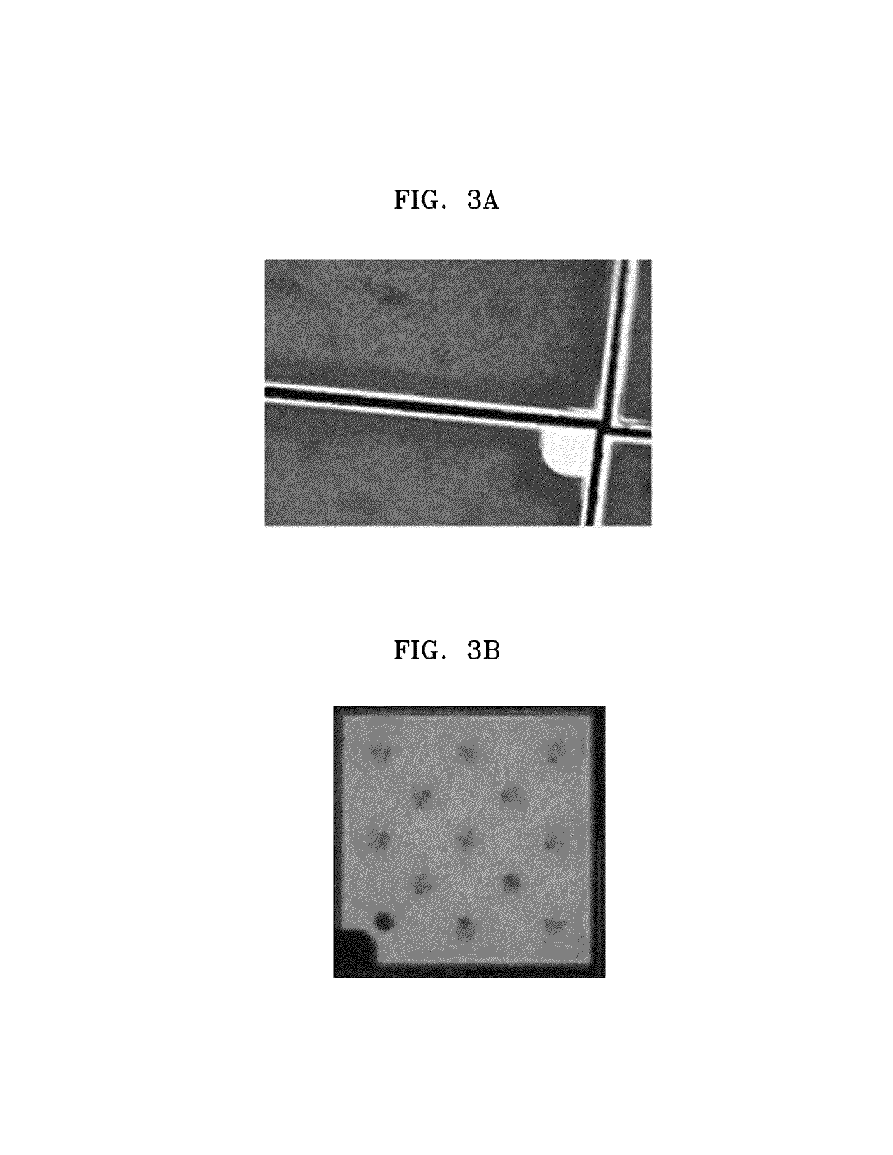

FIGS. 3A and 3B are top-view pictures of the LED chips manufactured according to exemplary embodiments described above.

FIG. 3A shows that a phosphor layer is properly formed on a plurality of LED chips. According to the method of manufacturing LED chips described above, a phosphor layer may be formed on the LEDs after a wafer and the LEDs are first-diced. Since the wafer and the LEDs are not completely separated in the first-dicing process, even if a dicing tape is expanded, the two-dimensional arrangement of the LEDs may be maintained. Therefore, the LEDs and a screen printing mask may be properly aligned, and thus, a phosphor layer may be properly formed only on the plurality of LEDs.

FIG. 3B shows that the phosphor layer of the LED chips is not contaminated by an impurity. According to the method of manufacturing LED chips described above, a phosphor layer may be formed on LEDs after a wafer and the LEDs are first-diced, and then a plurality of LED chips may be formed in a second-dicing process. Therefore, the phosphor layer may be prevented from being contaminated by materials constituting the LEDs and the wafer during a dicing process.

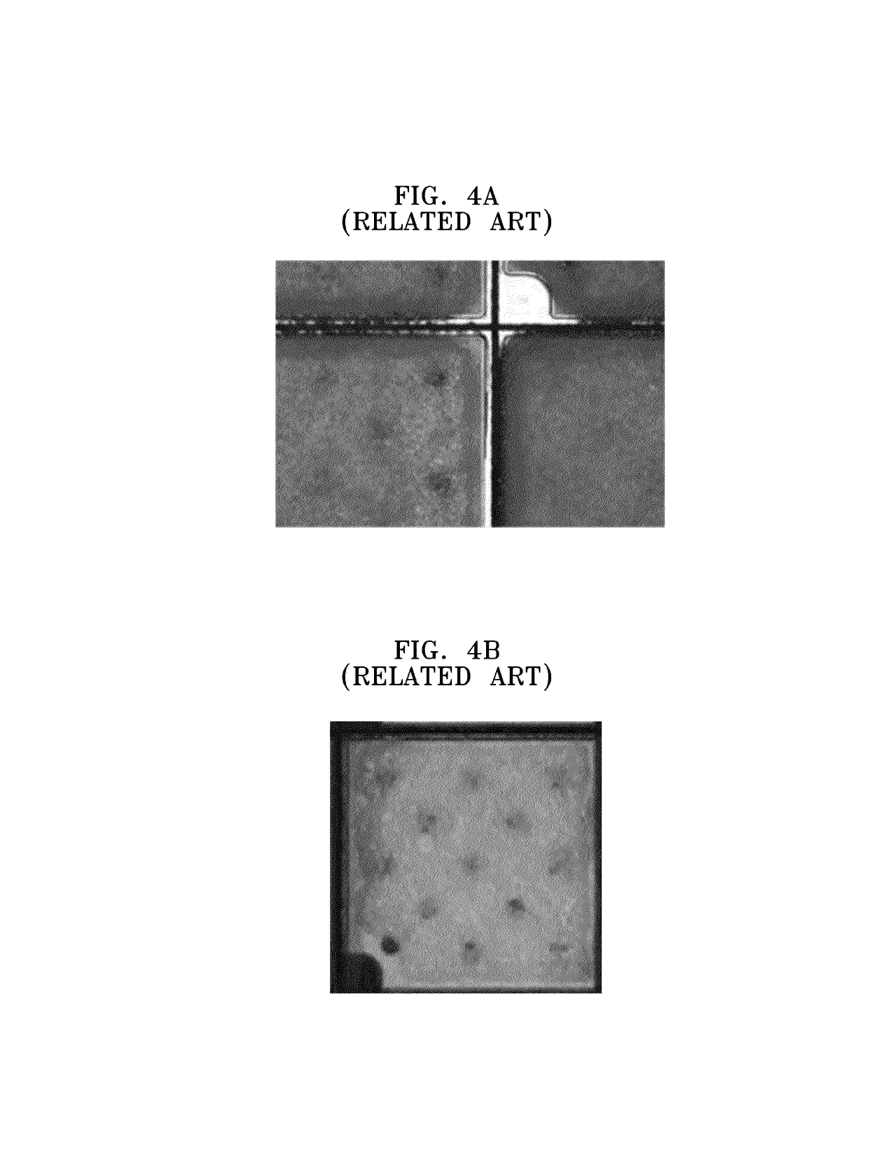

FIGS. 4A and 4B are top-view pictures of LED chips manufactured according to a method of manufacturing LED chips according to a comparative embodiment.

FIG. 4A shows that a phosphor layer is not properly formed on a plurality of LED chips and is partially dislocated. According to the method of manufacturing LED chips according to the comparative embodiment, a wafer and the LEDs are completely diced, and then a phosphor layer is formed on a plurality of LEDs by using a screen printing mask. In this case, a two-dimensional arrangement of the plurality of wafers and the plurality of LEDs that are completely diced is modified due to expansion of a dicing tape. Therefore, in the method of manufacturing LED chips according to the comparative embodiment, an alignment between a screen printing mask and the plurality of LEDs is modified, and thus, a phosphor layer is not be properly formed only on the plurality of LEDs and may be dislocated.

FIG. 4B shows that an edge portion of a phosphor layer of a LED chip is contaminated by an impurity. According to the method of manufacturing LED chips according to the comparative embodiment, a phosphor layer is formed on LEDs, and then a wafer and the LEDs are completely diced. Therefore, materials constituting the wafer and the LEDs may contaminate the phosphor layer during a dicing process.

According to the wafer dicing method described above, during an additional process for forming a layer formed of a predetermined material on a semiconductor device arranged on a wafer, the layer may be prevented from being contaminated by materials constituting the semiconductor layer and the wafer. Furthermore, modification of an alignment between the layer formed of a predetermined material and a mask may be prevented during the process of forming the layer on the semiconductor device.

The described-above exemplary embodiments and advantages are merely exemplary and are not to be construed as limiting. The present teaching can be readily applied to other types of apparatuses. The description of exemplary embodiments is intended to be illustrative, and not to limit the scope of the claims, and many alternatives, modifications, and variations will be apparent to those skilled in the art. Descriptions of features or aspects within each embodiment should typically be considered as available for other similar features or aspects in other embodiments.

What is claimed is:

1. A wafer dicing method comprising:
forming a semiconductor device on a first surface of a wafer;
first-dicing a first portion of the wafer and the semiconductor device to produce a plurality of semiconductor devices; and
splitting the wafer and the plurality of semiconductor devices into a plurality of semiconductor device chips by second-dicing a second portion of the wafer that has been first-diced.

2. The wafer dicing method of claim 1, wherein the first-dicing comprises forming, in the wafer, grooves having a depth corresponding to from 30% to 70% of a thickness of the wafer.

3. The wafer dicing method of claim 2, wherein the grooves comprise:
a plurality of first grooves formed on the wafer in parallel to a first direction; and
a plurality of second grooves formed on the wafer in parallel to a second direction that is perpendicular to the first direction.

4. The wafer dicing method of claim 1, wherein the first-dicing is performed by using a blade, a laser, or plasma etching.

5. The wafer dicing method of claim 1, wherein the second-dicing comprises breaking the second portion of the wafer that has been first-diced by applying a physical force to a second surface of the wafer which is a surface opposite to the first surface.

6. The wafer dicing method of claim 5, wherein the physical force is applied to the wafer via a cutter having an unsharpened edge.

7. The wafer dicing method of claim 1, further comprising attaching a dicing tape onto a second surface of the wafer which is a surface opposite to the first surface.

8. The wafer dicing method of claim 1, further comprising performing additional processes to the plurality of semiconductor devices subsequently to the first-dicing and prior to the second-dicing.

9. The wafer dicing method of claim 8, wherein the additional processes comprise forming an additional layer on the semiconductor devices.

10. A method of manufacturing light emitting device (LED) chips, the method comprising:
forming LED on a first surface of a wafer;
first-dicing a first portion of the wafer and the LED to produce a plurality of LEDs; and
splitting the wafer and the plurality of LEDs to a plurality of LED chips by second-dicing a second portion of the wafer that has been first-diced.

11. The method of claim 10, wherein the LED comprises a stacked structure in which an n-type semiconductor layer, an active layer, and a p-type semiconductor layer are stacked on the wafer in this order.

12. The method of claim 10, wherein the step first-dicing comprises forming, in the wafer, grooves having a depth corresponding to from 30% to 70% of a thickness of the wafer.

13. The method of claim 12, wherein the grooves comprise:
a plurality of first grooves formed in the wafer in parallel to a first direction; and
a plurality of second grooves formed in the wafer in parallel to a second direction that is perpendicular to the first direction.

14. The method of claim 10, wherein the first-dicing is performed by using a blade, a laser, or plasma etching.

15. The method of claim 10, wherein the second-dicing comprises breaking the second portion of the wafer that has been first-diced by applying a physical force to a second surface of the wafer which is a surface opposite to the first surface.

16. A method comprising:
forming a semiconductor device on a wafer;
partially dicing the wafer and the semiconductor device to produce grooves in the wafer and to produce a plurality of semiconductor devices disposed on corresponding partial wafer portions separated by the grooves;
completely dicing the wafer through the grooves to produce a plurality of semiconductor device chips.

17. The method of claim 16, wherein each of the grooves has a depth from approximately 30% to approximately 70% of a thickness of the wafer.

18. The method of claim 16, wherein the partially dicing the wafer comprises dicing through a first portion of the wafer proximate the semiconductor device, and the completely dicing the wafer comprises dicing through a second portion of the wafer into each of the grooves, by applying force to the second portion of the wafer in a direction of the grooves.

19. The method of claim 18, wherein a thickness of the first portion is approximately equal to a thickness of the second portion.

20. The method of claim 16, further comprising applying a phosphor layer on the plurality of semiconductor devices prior to the completely dicing the wafer.
